(19) United States
(12) Patent Application Publication
(10) Pub. No.: US 2016/0079500 A1
(43) Pub. Date: Mar. 17, 2016

(54) LIGHT EMITTING DEVICE AND MANUFACTURING METHOD THEREOF

(71) Applicant: KABUSHIKI KAISHA TOSHIBA, Tokyo (JP)

(72) Inventors: Hideo AOKI, Yokohama Kanagawa (JP); Kanako SAWADA, Yokohama Kanagawa (JP); Chiaki TAKUBO, Sumida Tokyo (JP)

(21) Appl. No.: 14/634,879

(22) Filed: Mar. 1, 2015

(30) Foreign Application Priority Data
Sep. 12, 2014 (JP) 2014-186753

(51) Int. Cl. H01L 33/62; H01L 33/56; H01L 33/50; H01L 33/60

(52) U.S. Cl. CPC H01L 33/62; H01L 33/60; H01L 33/56; H01L 33/507; H01L 33/505; H01L 2933/0033; H01L 2933/0041; H01L 2933/005; H01L 2933/0058; H01L 2933/0066

(57) ABSTRACT

A light emitting device includes a first lead frame having a top surface including a first region and a second region, a first metal layer disposed on the first region of the top surface, a reflector layer in contact with the second region of the top surface, a light emitting element mounted on the first metal layer and electrically connected to the first lead frame, and a transparent resin layer covering the light emitting element and in contact with the first metal layer.

### CROSS-REFERENCE TO RELATED APPLICATION

This application is based upon and claims the benefit of priority from Japanese Patent Application No. 2014-186753, filed Sep. 12, 2014, the entire contents of which are incorporated herein by reference.

### FIELD

Embodiments described herein relate generally to a light emitting device and a method of manufacturing the same.

### BACKGROUND

One type of a light emitting device uses an optical semiconductor as a light source. This kind of light emitting device includes a reflector layer made of resin having an opening formed therein, a lead frame coupled to the reflector layer, an optical semiconductor mounted inside the opening of the reflector layer and on the lead frame, and a transparent resin layer sealing the optical semiconductor. The optical semiconductor mounted on the lead frame is electrically connected to the lead frame using a bonding method such as wire bonding.

A metal layer, such as a layer containing Ag, is typically formed on a surface of the lead frame. The metal layer reflects a light emitted from the optical semiconductor towards a direction opposite to a light extraction direction of the light emitting device, and hence can enhances light emission efficiency of the light emitting device. The metal layer may also improve bonding strength between a wire and the optical semiconductor.

The metal layer, however, has a poor adhesion to the reflector layer, which is typically formed of resin; consequently the reflector layer may be peeled off from the metal layer formed on the lead frame. When the reflector layer is peeled off from the metal layer, the transparent resin layer provided on the reflector layer may also be peeled off from the metal layer, together with the reflector layer.

When the transparent resin layer is peeled off, the wire sealed by the transparent resin layer may be cut off as a result of receiving a force from the transparent resin layer.

Further, when the reflector layer is peeled off from the metal layer, water may seep into the light emitting device through the peeled-off position of the reflector layer. This water may oxidize the metal layer and deteriorate the reflectance of the metal layer. As a result, light emission efficiency of the light emitting device may be decreased.

### DESCRIPTION OF THE DRAWINGS

FIG. 1 is a schematic cross-sectional view of a light emitting device according to a first embodiment.

FIGS. 2A and 2B are a schematic cross-sectional view of a structure during manufacturing of the light emitting device of FIG. 1.

FIGS. 3A and 3B are a schematic view of the structure during manufacturing the light emitting device.

FIGS. 4A and 4B are a schematic view of a light emitting device according to a second embodiment.

FIGS. 5A to 5C are a schematic cross-sectional view of a structure during manufacturing of the light emitting device of FIGS. 4A and 4B.

FIGS. 6A and 6B are a schematic cross-sectional view of a structure during manufacturing of the light emitting device of FIGS. 4A and 4B.

FIG. 7 is a schematic cross-sectional view of the structure during manufacturing of the light emitting device of FIGS. 4A and 4B.

FIGS. 8A to 8C are a schematic cross-sectional view of a structure during manufacturing of a light emitting device according to a third embodiment.

### DETAILED DESCRIPTION

In general, according to one embodiment, alight emitting device includes a first lead frame having a top surface including a first region and a second region, a first metal layer disposed on the first region of the top surface, a reflector layer in contact with the second region of the top surface, a light emitting element mounted on the first metal layer and electrically connected to the first lead frame, and a transparent resin layer covering the light emitting element and in contact with the first metal layer.

Embodiments in the disclosure will be hereinafter described with reference to the drawings. The embodiments are not intended to restrict the scope of the present invention.

### First Embodiment

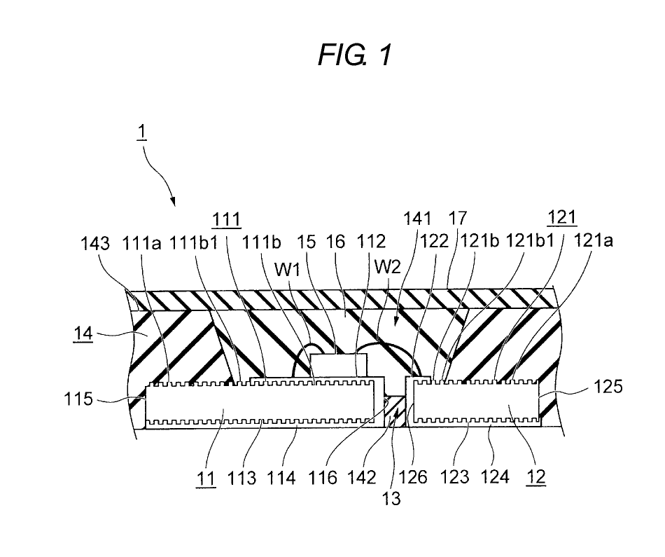

FIG. 1 is a schematic cross-sectional view of a light emitting device 1 according to a first embodiment. As illustrated in FIG. 1, the light emitting device 1 includes a first lead frame 11, a second lead frame 12, a reflector layer 14, an optical semiconductor 15, a transparent resin layer 16, and a phosphor layer 17.

The first lead frame 11 is formed in a plate shape and of a metallic material, including a top surface 111, which is a surface above which a light emitting element (optical semiconductor 15) is mounted and a bottom surface 113, which is a surface on a side of an external electrode for soldering. The top surface 111 includes a first fitting area 111a on which the reflector layer 14 is provided. Of the top surface 111, the first fitting area 111a is provided at an outer periphery of the light emitting device 1. The top surface 111 also includes a first element mounting area 111b in which the optical semiconductor 15 is mounted. Of the top surface 111, the first element mounting area 111b is positioned in the center portion of the light emitting device 1. The first element mounting area 111b is adjacent to the first fitting area 111a.

The first lead frame 11 is larger than the second lead frame 12 in the surface area. The first lead frame 11 may be an anode LED. The metallic material forming the first lead frame 11 is, for example, Cu; however, the material is not restricted to Cu, and alloy such as 42 Alloy may be used.

The second lead frame 12 is aligned next to the first lead frame 11 with a space 13 therebetween. The second lead frame 12 is formed in a plate shape and of a metallic material, including a top surface 121, which is a surface on a side of mounting the optical semiconductor 15 and a bottom surface 123, which is a surface on a side of the external electrode for soldering. The top surface 121 includes a second fitting area 121a where the reflector layer 14 is provided. Of the top surface 121, the second fitting area 121a is positioned at the outer periphery of the light emitting device 1. The top surface 121 also includes a second element mounting area 121b. Of the top surface 121, the second element mounting area 121b is positioned in the center portion of the light emitting device 1. The second element mounting area 121b is adjacent to the second fitting area 121a.

The second lead frame 12 may be a cathode LED. Although the metallic material used for the second lead frame 12 is, for example, the same as the metallic material used for the first lead frame 11, it may be different from the metallic material used for the first lead frame 11.

The reflector layer 14 is formed of, for example, a white resin. The white resin is a thermosetting resin or thermoplastic resin containing a high reflective filler. The reflector layer 14 is formed on the first fitting area 111a tightly. In other words, the first lead frame 11 is directly in contact with the reflector layer 14, in the first fitting area 111a. The reflector layer 14 is formed on the second fitting area 121a tightly. In other words, the second lead frame 12 is directly in contact with the reflector layer 14, in the second fitting area 121a. The reflector layer 14 is formed on an outer peripheral surface 115 of the first lead frame 11 and an outer peripheral surface 125 of the second lead frame 12 tightly.

In the reflector layer 14, an opening 141 is formed, and the opening 141 extends over the first element mounting area 111b and the second element mounting area 121b.

A white resin 142 similar to the reflector layer 14 is disposed in the space 13 between the first lead frame 11 and the second lead frame 12.

The optical semiconductor 15 is mounted on the first element mounting area 111b inside the opening 141 so that a light extraction surface is directed upward. In other words, the light extraction surface is positioned on the upper end surface of the optical semiconductor 15 illustrated in FIG. 1.

The optical semiconductor 15 is electrically connected to the first lead frame 11 through a first wire W1. Further, the optical semiconductor 15 is electrically connected to the second lead frame 12 through a second wire W2. One end of the second wire W2 is connected to the second element mounting area 121b of the second lead frame 12. When the optical semiconductor 15 includes an electrode on the bottom surface, electrical connection between the first lead frame 11 and the optical semiconductor 15 may be performed according to a die bonding. Although the optical semiconductor 15 is, for example, a blue LED, it is not restricted to the blue LED.

The transparent resin layer 16 is provided inside the opening 141 so as to seal the optical semiconductor 15. The transparent resin layer 16 may include an additive in order to adjust thermal conductivity, coefficient of thermal expansion, or modulus of elasticity. The transparent resin layer 16 may be any of thermoplastic resin and thermosetting resin.

The phosphor layer 17 is provided on an upper end surface 143 of the reflector layer 14 so as to cover the opening 141.

In the embodiment, the first fitting area 111a has a certain roughness. Further, the second fitting area 121a has a certain roughness.

As illustrated in FIG. 1, the first element mounting area 111b and the second element mounting area 121b may also have a certain roughness. As illustrated in FIG. 1, the bottom surface 113 of the first lead frame 11 and the bottom surface 123 of the second lead frame 12 may also have a certain roughness.

Arithmetic average roughness Ra of the roughness (or rough surface) is preferably 1 μm or less from the viewpoint of anchor effect of the rough surface and the viewpoint of increasing the adhered area of the reflector layer 14 according to an increase in the surface area or adhered interface. The arithmetic average roughness Ra is preferably in the range of several 10s nm to several 100s nm.

A first metal layer 112 is provided on the first element mounting area 111b. The first metal layer 112 is not provided on an area 111b1 along a lower end of the opening 141 in the first element mounting area 111b. The area 111b1 is directly in contact with the outer edge portion of the transparent resin layer 16.

A second metal layer 122 is provided on the second element mounting area 121b. The second metal layer 122 is not provided on an area 121b1 along a lower end of the opening 141 in the second element mounting area 121b. The area 121b1 is directly in contact with the outer edge portion of the transparent resin layer 16.

The first metal layer 112 and the second metal layer 122 reflect the light from the optical semiconductor 15. As a result, emission efficiency of the light emitting device 1 may be increased, and bonding performance of the first bonding wire W1 and the second wire W2 may be improved. Although the metal layers 112 and 122 are, for example, an Ag layer containing Ag, the metal layers may contain a metallic material other than Ag, such as Zn, Sn, Pd, Pt and Au.

As illustrated in FIG. 1, a metal layer 114 is also provided on the bottom surface 113 of the first lead frame 11. Further, a metal layer 124 is also provided on the bottom surface 123 of the second lead frame 12. The metal layers 114 and 124 on the bottom surfaces 113 and 123 may improve soldering performance with the external electrode.

As illustrated in FIG. 1, a metal layer 116 is provided on an inner surface defining the space 13 in the first lead frame 11. A metal layer 126 is also provided on the inner surface defining the space 13 in the second lead frame 12.

Here, as mentioned above, the first metal layer 112 and the second metal layer 122 increase the emission efficiency of the light emitting device 1 and improve the bonding performance of the optical semiconductor 15.

When the metal layer is also provided on the first fitting area 111a and the second fitting area 121a, the resin reflector layer 14 would have a poor adhesion to the metal layer; therefore, the reflector layer 14 may be occasionally peeled off from the lead frames 11 and 12.

When the reflector layer 14 is peeled off from the lead frames 11 and 12, the transparent resin layer 16 adhered to the reflector layer 14 may be also peeled off from the lead frames 11 and 12 together with the reflector layer 14. When the transparent resin layer 16 is peeled off, a force applied to the transparent resin layer 16 may negatively affect the wires W1 and W2 sealed by the transparent resin layer 16 and cause a break of the wires W1 and W2.

When the reflector layer 14 is peeled off from the lead frames 11 and 12, water may intrude into the light emitting device 1 through the peeled-off position of the reflector layer 14. This water may oxidize the metal layers 112 and 122 deteriorate the reflectance of the metal layers 112 and 122.

Therefore, when the metal layer is formed on the fitting areas 111a and 121a, a wire breakage and deterioration of the reflectance may happen; as a result, it mays not be able to obtain a long-term reliability in emission efficiency and bonding performance.

In order to improve the adhesion of the reflector layer 14 with the lead frames 11 and 12, the surface of the metal layers 112 and 122 might have a certain roughness at a contact portion with the reflector layer 14. However, it would be difficult to roughen the metal layers 112 and 122, and a method of roughening the metal layers 112 and 122 would not be realistic.

Further, in order to improve the adhesion of the reflector layer 14 with the lead frames 11 and 12, a slit or a step shape by half-etching might be formed in the bottom surfaces 113 and 123 of the lead frames 11 and 12 and in the space 13 thereof. When the reflector layer 14 is molded on the lead frames 11 and 12, the slit or the step shape allows the resin material of the reflector layer 14 to reach the bottom surfaces 113 and 123 of the lead frames 11 and 12, and would increase the contact area of the lead frames 11 and 12 with the reflector layer 14.

However, when the slit or the step shape is provided in the lead frames 11 and 12, the lead frames 11 and 12 have to be thick enough to have a mechanical strength to be able to endure the processing of the slit or the step shape. The necessity of the thick lead frames 11 and 12 would increase the use amount of the material for the lead frames 11 and 12, thereby increasing the cost. Further, additional process for the half-etching would increase the cost further. When a slit is formed in the first lead frame having a large area, a heat radiation path from the optical semiconductor 15 would be broken and deteriorate heat dissipation.

To the contrary, according to the embodiment, the first metal layer 112 and the second metal layer 122 improve the reflectance and the bonding performance, and the roughness of the first fitting area 111a and the roughness of the second fitting area 121a may improve the adhesion of the reflector layer 14. The good adhesion of the reflector layer 14 may suppress a wire break that may be caused by the removal of the transparent resin layer 16 according to the removal of the reflector layer 14 and the oxidization of the metal layers 112 and 122 that may be caused by the water intrusion according to the removal of the reflector layer 14. As a result that the wire break and the oxidization of the metal layers 112 and 122 may be suppressed, a long-term reliability may be improved in the emission efficiency of the light emitting device 1 and the bonding performance of the optical semiconductor 15.

In the embodiment, in order to secure the adhesion of the lead frames 11 and 12 with the reflector layer 14, it is not necessary to prepare a thicker lead frames 11 and 12 and form any slit or step shape in the lead frames 11 and 12. As the result of no need of forming any slit or step shape, the cost may be reduced while suppressing the use amount of the material of the lead frames 11 and 12, and the heat radiation path of the optical semiconductor 15 may be secured.

The material of the transparent resin layer 16 is prioritized in moisture permeability over adhesion, from the viewpoint of improving optical property of the light emitting device 1 and the viewpoint of inhibiting a reduction in the reflectance that may be caused by the oxidization of the metal layers 112 and 122. The transparent resin layer 16 having high moisture permeability tends to be negatively affected by a thermal stress in a direction of removing the transparent resin layer 16 from the lead frames 11 and 12, which is caused by a difference of a thermal expansion coefficient between the transparent resin layer 16 and the lead frames 11 and 12. The thermal stress tends to become larger in the outer edge portion of the transparent resin layer 16.

In the embodiment, however, the outer edge portion of the transparent resin layer 16 is directly in contact with the area 111b1 of the first element mounting area 111b having the certain roughness. Further, the outer edge portion of the transparent resin layer 16 is directly in contact with the area 121b1 of the second element mounting area 121b having the certain roughness. The area 111b1 and the area 121b1 may secure the greater adhesion than the thermal stress that functions in a way to peel off the transparent resin layer 16, between the outer edge portion of the transparent resin layer 16 and the lead frames 11 and 12, thereby restraining the transparent resin layer 16 from being peeled off. Since the transparent resin layer 16 may be restrained from being peeled off, a break of the wires W1 and W2 and a reduction in the reflectance that may be caused by the intrusion of water may be further effectively restrained.

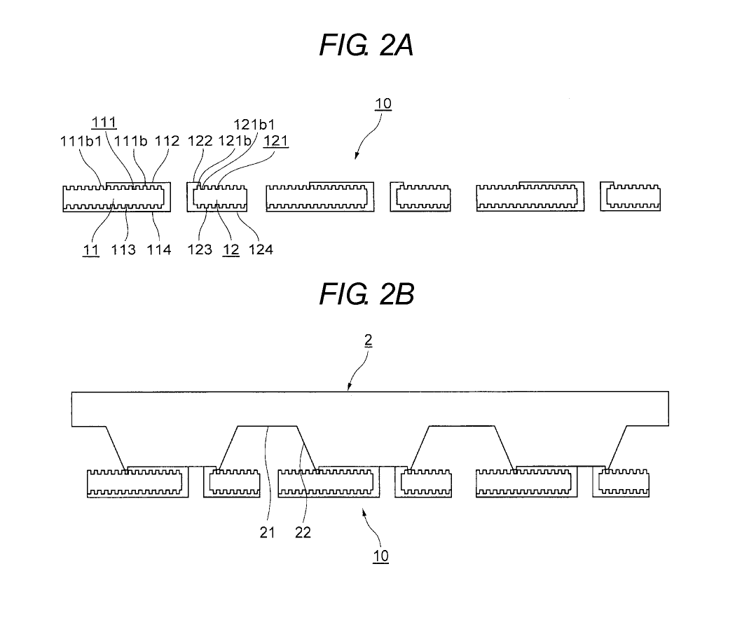

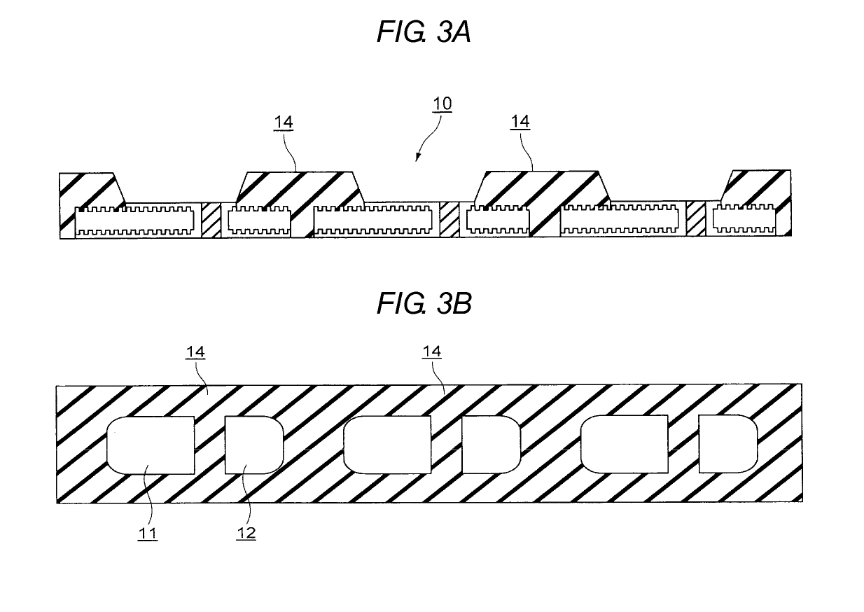

FIGS. 2A and 2B are a schematic cross-sectional view during the manufacturing of the light emitting device 1 of FIG. 1. FIG. 2A illustrates a process of forming a large lead frame, and FIG. 2B illustrates a process of mounting a mold. FIGS. 3A and 3B are a schematic cross-sectional view during the manufacturing of the light emitting device 1 of FIG. 1, following FIG. 2B. FIG. 3A illustrates a removal process of the mold after forming the reflector layer 14, and FIG. 3B is a bottom surface view of FIG. 3A. Hereinafter, the method of manufacturing the light emitting device 1 of FIG. 1 will be described using FIGS. 2A and 2B and FIGS. 3A and 3B.

According to the method of manufacturing the light emitting device 1 in the embodiment, first, as illustrated in FIG. 2A, a large lead frame 10 corresponding to a plurality of light emitting devices 1 (refer to FIG. 1) is formed. The large lead frame 10 includes a plurality of the component units aligned at intervals, and each component unit includes the first lead frame 11 and the second lead frame 12 corresponding to one light emitting device 1. The respective component units are connected to each other through a connection portion (not illustrated).

In the large lead frame 10, the first lead frame 11 is has a roughness on most surface regions of both the top surface 111 and the bottom surface 113. Further, the second lead frame 12 has a roughness on most surface regions of both the top surface 121 and the bottom surface 123. The first and second lead frames 11 and 12 may be roughened according to the surface roughening processing of the lead frames 11 and 12. The roughening processing may be performed, for example, using etching, oxidization, machinery processing, or plating.

Further, the first metal layer 112 is formed on the top surface 111 of the first lead frame 11 across the area of the first element mounting area 111b other than the area 111b1. The metal layer 114 is formed on the bottom surface 113 of the first lead frame 11. The second metal layer 122 is formed on the top surface 121 of the second lead frame 12 across the area of the second element mounting area 121b other than the area 121b1. The metal layer 124 is formed on the bottom surface 123 of the second lead frame 12. The metal layers 112, 122, 114, and 124 may be formed, for example, using the plating process.

Next, as illustrated in FIG. 2B, a mold (upper mold) 2 is placed on the large lead frame 10. The mold 2 includes a shape transfer surface 21 corresponding to the upper end surface 143 (refer to FIG. 1) of the reflector layer 14 and a shape transfer surface 22 corresponding to the inner peripheral surface of the opening 141 of the reflector layer 14, for each light emitting device 1. The shape transfer surfaces 21 corresponding to the upper end surfaces 143 of the adjacent reflector layers 14 are continuous so as to reduce a waste of the white resin. The large lead frame 10 is mounted on a base (lower mold), not illustrated, facing the mold 2. The white resin, which is a material of forming the reflector layer 14, is injected into a space (cavity) surrounded by the mold 2 and hardened. The process illustrated in FIG. 2B may be performed, for example, using the transfer molding process.

As illustrated in FIG. 3A, the large lead frame 10 with the reflector layer 14 is separated from the mold 2, and the large lead frame 10 with the reflector layer 14 is obtained. At this point, the reflector layer 14 for every light emitting device 1 is an integral resin body, as illustrated in FIG. 3B.

Each optical semiconductor 15 is die-bonded to the large lead frame 10 where the reflector layer 14 has been formed according to FIGS. 3A and 3B. In the die bonding, the optical semiconductor 15 is attached on the first element mounting area 111b of the first lead frame 11 inside the opening 141 with a mounting material. Then, a first electrode (for example, p-electrode) of the optical semiconductor 15 is connected to the first lead frame 11 through the first wire W1. A second electrode (for example, n-electrode) of the optical semiconductor 15 is connected to the second lead frame 12 through the second wire W2 (wire bonding).

Then, the transparent resin layer 16 is formed inside the opening 141 to seal the optical semiconductor 15. The transparent resin layer 16 may be formed using dropping molding (potting), injection molding, or extrusion molding.

The phosphor layer 17 of one large sheet shape is attached to each upper end surface 143 of the reflector layer 14 with respect to every light emitting device 1 to cover each opening 141. The sheet-shaped phosphor layer 17 is obtained by molding a resin using press working, rolling, or potting.

The large lead frame 10, the reflector layer 14, and the phosphor layer 17 are divided into pieces for every light emitting device 1 by a blade, and a plurality of individual light emitting devices 1 is obtained.

In the manufacturing method according to the embodiment, manufacturing cost and time may be reduced by using the sheet-shaped phosphor layer 17, compared with the case of forming the phosphor layer using the potting after a transparent resin is formed. Further, it is possible to restrain the dispersion in color tone while in use by enhancing the controllability of thickness.

### Second Embodiment

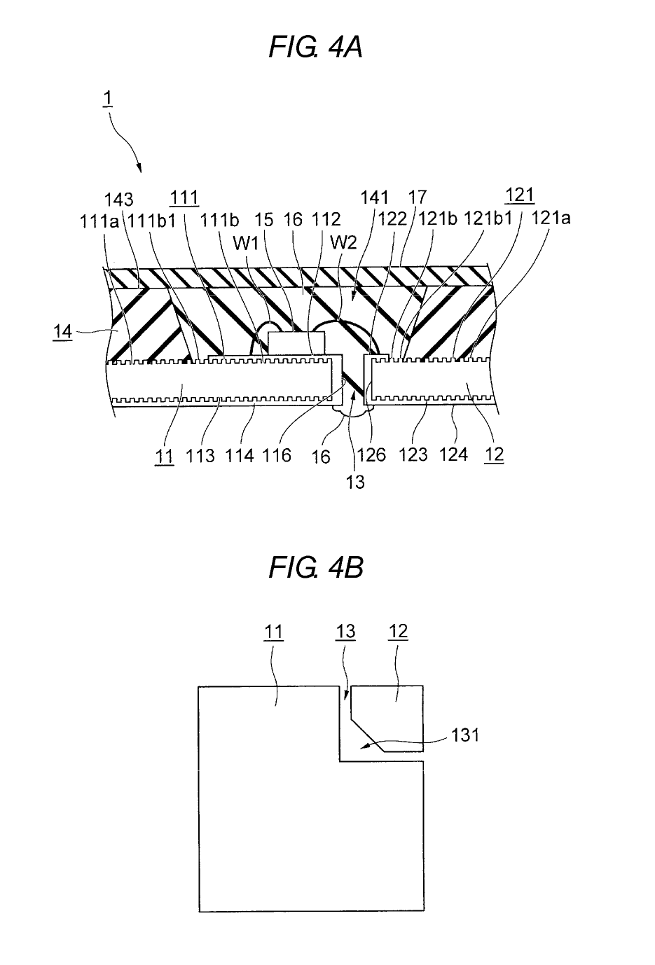

Next, a second embodiment will be described. In the description of the embodiment, the same reference numerals are used to the same components as in the first embodiment and their description is omitted. FIGS. 4A and 4B are a schematic view of a light emitting device 1 according to the second embodiment; specifically, FIG. 4A is a schematic cross-sectional view and FIG. 4B is a schematic bottom surface view.

As illustrated in FIG. 4A, in the light emitting device 1 according to the embodiment, a transparent resin layer 16 is provided in a space 13 between a first lead frame 11 and a second lead frame 12. The transparent resin layer 16 protrudes from the space 13 to the side of bottom surfaces 113 and 123 of the lead frames 11 and 12.

As illustrated in FIG. 4B, the space 13 in the embodiment has a curving shape in a plane view. A corner 131 of the space 13 is formed larger in room than the other portion of the space 13. When forming the transparent resin layer 16, the corner 131 works as a filling hole 131 for transparent resin. The other components may be fundamentally the same as the first embodiment.

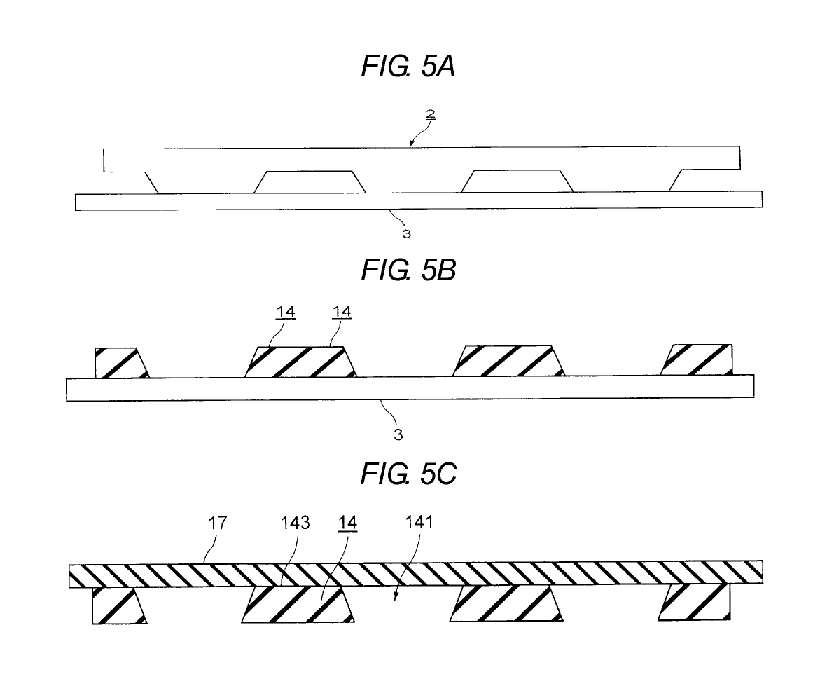

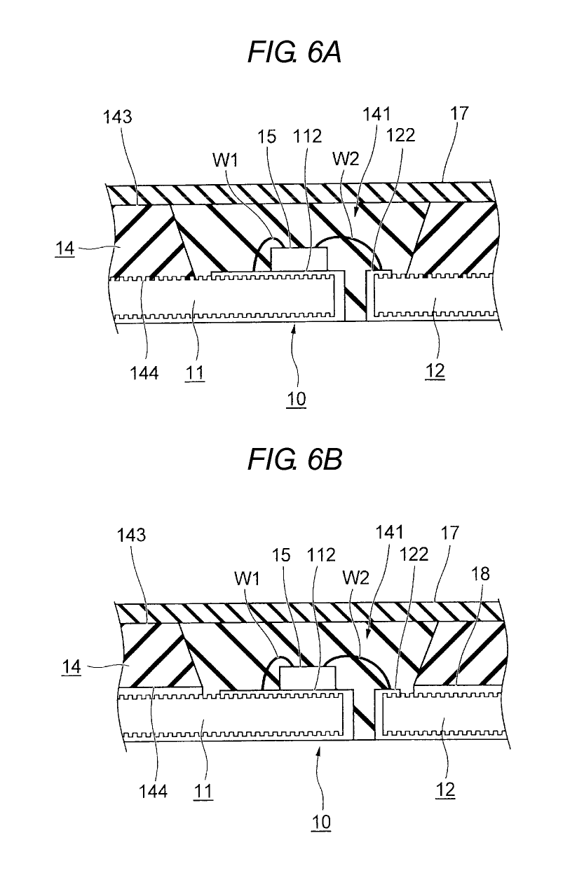

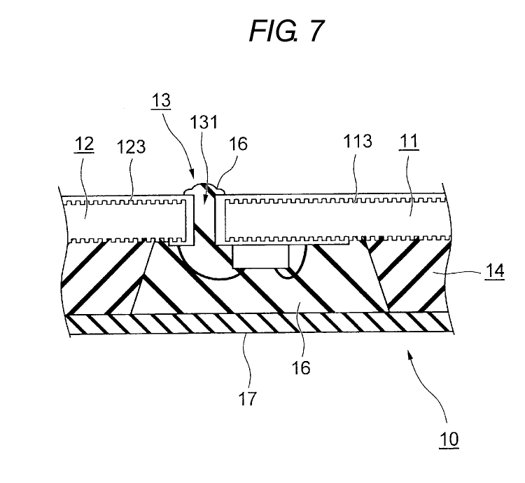

FIGS. 5A to 5C are a schematic cross-sectional view of a structure during manufacturing of the light emitting device 1 of FIGS. 4A and 4B: FIG. 5A illustrates a process of holding a mold 2, FIG. 5B illustrates a separation process of the mold after forming a reflector layer 14, and FIG. 5C is a schematic cross-sectional view of the reflector 14 with a phosphor layer attached thereto. FIGS. 6A and 6B are a schematic cross-sectional view of a structure during the manufacturing of the light emitting device 1 of FIGS. 4A and 4B, following the process of FIG. 5C. FIG. 6A illustrates a process of attaching a wire-bonded large lead frame 10, and FIG. 6B illustrates a modified example of FIG. 6A. FIG. 7 is a schematic cross-sectional view of a structure during the manufacturing of the light emitting device 1 in FIGS. 4A and 4B, following the process of FIGS. 6A and 6B, illustrating an injection process of transparent resin. Hereinafter, with reference to FIGS. 5A to 7, the method of manufacturing the light emitting device 1 in FIGS. 4A and 4B will be described.

In the method of manufacturing the light emitting device 1 according to the embodiment, first, as illustrated in FIG. 5A, the mold 2 is placed on a plate 3 having a heat resistance enough to endure the temperature of the molding process.

As illustrated in FIG. 5B, a white resin, which is a material of the reflector layer 14, is injected in the space surrounded by the mold 2 and hardened, and an integral resin body of the reflector layer 14 is formed for every light emitting device 1 on the plate 3.

As illustrated in FIG. 5C, a large sheet shaped phosphor layer 17 is attached (jointed) to each upper end surface 143 of the reflector layer 14 for every light emitting device 1 to cover each opening 141. Then, the plate 3 is removed. The plate 3 may be removed before the phosphor layer 17 is attached.

As illustrated in FIG. 6A, a wire-bonded large lead frame 10 is attached (adhered) to a lower end surface 144 of the reflector layer 14. An optical semiconductor 15 is disposed within the opening 141. Here, in FIG. 6A, since the reflector layer 14 is made of a material having adhesion, the large lead frame 10 is directly attached to the reflector layer 14. If the reflector layer 14 does not have an adhesive property, the reflective layer 14 can be attached to the large lead frame 10 with an adhesive sheet 18, as illustrated in FIG. 6B.

As illustrated in FIG. 7, a transparent resin is injected into the opening formed by the reflector layer 14 and the space 13 through the injection hole 131 of the space 13 using the potting. The transparent resin protrudes a little from the space 13 towards outside of the bottom surfaces 113 and 123 of the first lead frame 11 and the second lead frame 12 of the large lead frame 10. According to this, the transparent resin layer 16 is formed.

By dividing the large lead frame 10, the reflector layer 14, and the phosphor layer 17 into pieces, each corresponding to a light emitting device 1, using a blade, a plurality of light emitting devices 1 is obtained.

According to the embodiment, as a part of the transparent resin layer 16 protrudes to the side of the bottom surfaces 113 and 123 of the lead frames 11 and 12, the transparent resin layer 16 may securely hold the lead frames 11 and 12, functioning as a rivet.

In the transfer molding process, a white resin of the reflector layer 14 may be introduced into the side of the bottom surfaces 113 and 123 of the lead frames 11 and 12, as a method of securing adhesion of the transparent resin layer 16 with the lead frames 11 and 12. When this method is adopted, adhesion of the reflector layer 14 with the lead frames 11 and 12 is improved and adhesion of the transparent resin layer 16 with the lead frames 11 and 12 may possibly be secured indirectly through the adhesion of the reflector layer 14 with the lead frames 11 and 12.

However, when the method of introducing the white resin of the reflector layer 14 to the side of the bottom surfaces 113 and 123 of the lead frames 11 and 12 is adopted, burrs of the white resin may be produced on the bottom surfaces 113 and 123 of the lead frames 11 and 12. Since the burrs of the white resin deteriorate the quality of the appearance of the light emitting device 1, the burrs should be removed. In the deburring process, by transmitting a deburring force reacting on the burrs to the reflector layer 14, the reflector layer 14 may also be removed. As the result of removing the reflector layer 14, it is not possible to keep well the adhesion of the reflector layer 14 with the lead frames 11 and 12 and the adhesion of the transparent resin layer 16 with the lead frames 11 and 12.

To the contrary, in the embodiment, since the potting is used to protrude the transparent resin layer 16 to the side of the bottom surfaces 113 and 123, burrs are not likely to be produced in the transparent resin layer 16. Since the transparent resin layer 16 that is not distinctive in the appearance view is protruded, any problem on a quality level does not occur even if burrs are produced. Compared with the case of applying a transparent resin several times, cost and time may be reduced.

### Third Embodiment

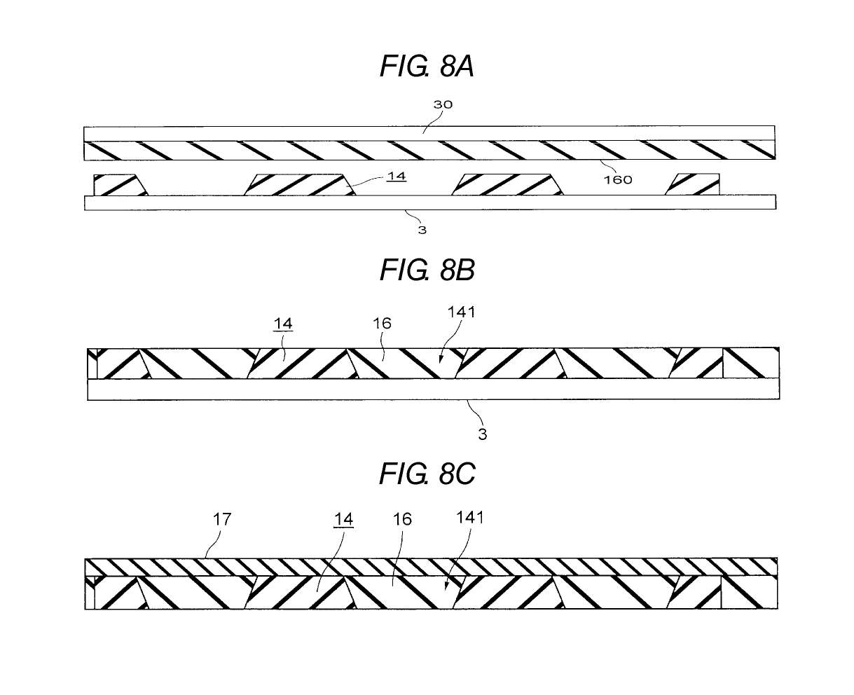

Next, a third embodiment will be described. In the description of the third embodiment, the same reference numerals are used for the same components as in the first embodiment and the overlapping description is omitted. FIGS. 8A to 8C are a schematic cross-sectional view of a structure during manufacturing of a light emitting device 1 according to the third embodiment: FIG. 8A illustrates a supply process of a Film on die (FOD); FIG. 8B illustrates a removal process after a transparent resin layer 16 is formed; and FIG. 8C illustrates an attachment process of a phosphor layer 17.

In the manufacturing method of the present embodiment, the FOD is used for manufacturing the light emitting device 1 including the reflector layer 14 similar to the second embodiment.

Specifically, in the present embodiment, after finishing the molding process of the reflector layer 14 similar to FIG. 5B, as illustrated in FIG. 8A, an FOD 160 of a transparent resin supported by a plate 30 is pressed against the reflector layer 14, using a pressing device (not illustrated). By pressing the FOD 160, the transparent resin of the FOD 160 is transferred into (positioned inside) an opening 141 of the reflector layer 14.

As illustrated in FIG. 8B, the plate 30 is removed, to leave the transparent resin layer 16 inside the openings 141.

As illustrated in FIG. 8C, by attaching the phosphor layer 17 to the reflector layer 14 and the transparent resin layer 16, a composite sheet including the reflector layer 14, the transparent resin layer 16, and the phosphor layer 17 is obtained.

A wire-bonded large lead frame 10 is attached to the composite sheet obtained in FIG. 8C so that respective optical semiconductors 15 may be positioned inside the respective openings 141. After that, the transparent resin layer 16 is hardened. Then, the large lead frame 10, the reflector layer 14, and the phosphor layer 17 are divided into pieces, each corresponding to one light emitting device 1, and a plurality of light emitting devices 1 is obtained.

According to the present embodiment, by using the FOD, burrs of the transparent resin layer 16 may not be produced, thereby preventing a problem of resin removal caused by the deburring from arising.

A method for manufacturing a light emitting device, according to an embodiment, includes the steps of forming a reflector layer having an opening, on a plate, forming a transparent resin layer inside the opening, forming a phosphor layer on upper surfaces of the reflector layer and the transparent resin layer, and removing the plate and attaching, to a lower surface of the reflector layer, a first lead frame on which a light emitting element is mounted and a second lead frame located adjacent to the first lead frame with a space therebetween, such that the light emitting element is embedded in the transparent resin layer.

A method for manufacturing a light emitting device, according to another embodiment, includes the steps forming a first metal layer partially on a first region of a top surface of a first lead frame and not on a second region of the top surface of the first lead frame, forming a second metal layer partially on a third region of a top surface of a second lead frame and not on a fourth region of the top surface of the second lead frame, the second lead frame being located adjacent to the first lead frame with a space therebetween, forming a reflector layer directly on the second region of the first lead frame and the fourth region of the second lead frame, mounting a light emitting element on the first metal layer, electrically connecting the light emitting element to the first and the second lead frames, and covering the light emitting element with a transparent resin layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A light emitting device comprising:
a first lead frame having a top surface including a first region and a second region;
a first metal layer disposed on the first region of the top surface;
a reflector layer in contact with the second region of the top surface;
a light emitting element mounted on the first metal layer and electrically connected to the first lead frame; and
a transparent resin layer covering the light emitting element and in contact with the first metal layer.

2. The light emitting device according to claim 1, wherein
a portion of the first region is not covered by the first metal layer, and the transparent resin layer is in contact with the first region at the portion of the first region.

3. The light emitting device according to claim 2, wherein the portion of first region is adjacent to the second region.

4. The light emitting device according to claim 1, further comprising:
a phosphor layer disposed on upper surfaces of the reflector layer and the transparent resin layer.

5. The light emitting device according to claim 1, wherein the first metal layer includes Ag.

6. The light emitting device according to claim 1, further comprising:
a second lead frame disposed adjacent to the first lead frame with a space therebetween, and having a top surface including a third region and a fourth region, and the reflector layer is in contact with the fourth region.

7. The light emitting device according to claim 6, wherein the light emitting element is electrically connected to the second lead frame.

8. The light emitting device according to claim 6, further comprising:
a second metal layer disposed on the third region and electrically connected to the second lead frame.

9. The light emitting device according to claim 8, wherein
a portion of the third region is not covered by the second metal layer, and the transparent resin layer is in contact with the third region at the portion of the third region.

10. The light emitting device according to claim 9, wherein
the portion of the third region is adjacent to the fourth region.

11. The light emitting device according to claim 8, wherein the second metal layer includes Ag.

12. A light emitting device comprising:
a first lead frame;
a second lead frame disposed adjacent to the first lead frame with a space therebetween;
a light emitting element disposed on and electrically connected to the first lead frame;
a reflector layer that is made of resin, disposed directly on parts of the first and second lead frames;
a transparent resin layer covering the light emitting element and surrounded by the reflector layer; and
a phosphor layer disposed on an upper surface of the reflector layer.

13. The light emitting device according to claim 12, further comprising:
a first metal layer disposed on a top surface of the first lead frame, wherein
the light emitting element is disposed directly on the first metal layer, and
a portion of the first lead frame is not covered by the first metal layer, and the transparent resin layer is in contact with the first lead frame at the portion of the first lead frame.

14. The light emitting device according to claim 13, further comprising:
a second metal layer disposed on a top surface of the second lead frame, wherein
a portion of the second lead frame is not covered by the second metal layer, and the transparent resin layer is in contact with the second lead frame at the portion of the second lead frame.

15. A method for manufacturing a light emitting device, comprising:
forming a reflector layer having an opening, on a plate;
forming a phosphor layer on an upper surface of the reflector layer, so as to cover the opening;
removing the plate and attaching, to a lower surface of the reflector layer, a first lead frame on which a light emitting element is mounted and a second lead frame located adjacent to the first lead frame with a space therebetween, such that the light emitting element is located within the opening; and
disposing a transparent resin in the opening between the first lead frame and the second lead frame.

16. The method according to claim 15, wherein
the disposing of the transparent resin includes potting a fluid transparent resin material into the opening and curing the fluid transparent resin material.

17. The method according to claim 15, wherein
the transparent resin is disposed to as to protrude from bottom surfaces of the first and second lead frames.
